(19) United States
(12) Patent Application Publication
(10) Pub. No.: US 2025/0189935 A1
(43) Pub. Date: Jun. 12, 2025

(54) Electronic Device with Isolated Button Member

(71) Applicant: Apple Inc., Cupertino, CA (US)

(72) Inventors: Nicholas L. Qu, Vancouver (CA); Patrick J. Crowley, Santa Clara, CA (US); Sameer Pandya, Sunnyvale, CA (US); Jafir A. Haidri, San Francisco, CA (US); Muhammad Ahmadi, Santa Clara (CA)

(21) Appl. No.: 18/533,601

(22) Filed: Dec. 8, 2023

(51) Int. Cl. G04G 21/02; G04G 21/08; G06F 1/16; G06F 3/02; H01H 3/12; H03K 17/96

(52) U.S. Cl. CPC G04G 21/025; G04G 21/08; G06F 1/163; G06F 1/1656; G06F 3/0202; H01H 3/12; H03K 17/96

(57) ABSTRACT

An electronic device, such as a watch, may include a crown and a button assembly alongside an external side surface the device. The button assembly may have a button portion that includes a cap, a base, an electrical component, and an intermediate structure overmolded between the cap and the base. The intermediate structure may encapsulate the electrical component. Due to this configuration, a cap can be effectively electrically isolated from the base at certain states or electrically coupled under different states dictated by the electrical component.

### TECHNICAL FIELD

The subject matter of this disclosure relates generally to electronic devices, and more particularly, to electronic devices with button assemblies configured to receive inputs.

### BACKGROUND

Electronic devices such as mobile phones, tablet computers, wearable devices, and the like may include input systems, such as buttons, crowns, dials, and the like, which can detect a variety of inputs or other signals. For example, a watch or other electronic device may include a button that can be pushed in order to provide inputs to the device. As another example, a watch may include a crown that can receive rotational and/or translational inputs. Such input systems may be used in various combinations to provide input functionality to a device.

### SUMMARY

A portable electronic device may include: a housing defining an external side surface; and a button assembly positioned along the external side surface of the housing and having a button portion. The button portion may include a metal base movably coupled to the housing; a metal cap coupled to the metal base and defining a user input surface; an intermediate structure having a dielectric material positioned between the metal cap and the metal base, the intermediate structure bonding the metal cap to the metal base; and an electrical component positioned in the intermediate structure and between the metal cap and the metal base, the electrical component conductively coupled to the metal cap and the metal base.

In some cases, the portable electronic device further includes an electrode positioned along the external side surface of the housing and configured to contact a first portion of a user's finger; a biometric sensing system configured to measure a physiological parameter of a user based at least in part on a signal from the electrode; and where the intermediate structure of the button portion electrically isolates a second portion of the user's finger that is that is in contact with the user input surface from the housing.

In some examples, the dielectric material at least partially encapsulates the electrical component. The electrical component may be a transient voltage suppression diode configured to conductively decouple the metal cap from the metal base under a first condition and conductively couple the metal cap to the metal base under a second condition. The electrical component may include a fuse. In some cases, the button assembly further includes a printed circuit board at least partially embedded in the intermediate structure; and the electrical component is coupled to the printed circuit board. The user input surface may protrude from the external side surface and the metal base may be recessed with respect to the external side surface.

An electronic watch may include a display; a housing at least partially surrounding the display, the housing defining an external side surface; a first input member defining a first user input surface, the first input member positioned along the external side surface of the housing, the first input member configured to receive a signal from a portion of a user's skin in contact with the first user input surface; a second input member positioned along the external side surface of the housing. The second input member may include a metal cap defining a second user input surface, a metal base movably coupled to the housing, and an intermediate structure between the metal cap and the metal base, the intermediate structure comprising a dielectric material configured to conductively isolate the metal cap from the metal base.

In some cases, the first input member is a crown configured to receive a rotational input; the signal received is detected by an electrocardiogram sensor configured to measure a physiological parameter of the user; and the second input member is a button configured to receive a translational input.

As another example, the electronic watch may further include an electrical component electrically coupled to the metal cap and the metal base, the electrical component embedded in the intermediate structure.

In some examples, the dielectric material has a molded polymer material that bonds the metal cap to the metal base; and the dielectric material separates the metal cap and the metal base. The electrical component may be a transient-voltage-state (TVS) diode configured to isolate the metal cap from the metal base at a voltage range comprising an ECG signal voltage. The TVS diode may be configured to conduct current from the metal cap to the metal base to ground the metal cap at an electrostatic discharge voltage. The electrical component may be configured to conductively couple the metal cap to the metal base in response to a voltage condition between the metal cap and the metal base.

An electronic device may include a metal housing and a button assembly. The button assembly may include a button portion positioned partially within a recess defined by the metal housing, the button portion configured to be depressed by a user input applied thereto, the button portion having: a cap defining a conductive surface and configured to receive the user input; a base conductively coupled to the metal housing; an electrical component coupled to the cap and to the base, the electrical component configured to in a first state, conduct current from the cap to the base, and in a second state, effectively isolate the cap to the base; and a polymer member formed between the cap and the base and mechanically coupled to the electrical component.

In some cases, the button portion further includes a gasket positioned over a portion of a peripheral surface of the button portion, the gasket concealing a peripheral surface of the polymer member. The electrical component may be encapsulated in the polymer member and electrically coupled to the cap or the base.

The polymer member may be formed within a gap defined between the cap and the base. The electrical component may be soldered to the cap and the base. The polymer member may define a gasket portion configured to define a seal between the button portion and the metal housing.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIGS. 1A and 1B depict an example electronic device including a button assembly, such as described herein.

FIG. 1C depicts a cross-sectional view of the device from FIGS. 1A and 1B.

FIG. 2 depicts a cross-sectional view of a button assembly.

FIGS. 3A-3E depict cross-sectional views of example button portions.

FIGS. 4A-4E depict example equivalent circuits of a button assembly.

FIGS. 5A and 5B depict example mechanical couplings of a button portion.

FIGS. 6A and 6B depict perspective views of an example electronic device.

FIG. 6C depicts a cross-sectional view of an example electronic assembly.

FIG. 7 depicts an example electronic device that may include a button assembly.

FIG. 8 depicts example components of the electronic device.

The use of the same or similar reference numerals in different figures indicates similar, related, or identical items.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein relate to electronic devices. In particular, embodiments described herein are directed to button assemblies that can have different electrical characteristics between a cap of the button assembly and a body of the button assembly under different conditions. For example, the button assembly may be configured to electrically isolate the cap from the base under certain voltage and/or current conditions (e.g., during a sensing operation), but also conduct electricity under other voltage and/or current conditions (e.g., an electrostatic discharge (ESD) condition).

In small electronic devices, user input controls, such as crowns and buttons, are often adjacent to each other for user accessibility and because of restrictions in space. For example, electronic watches generally include only two sides where the button and the crown can be placed for the user to conveniently access (e.g., the left and right lateral sides). Many of these electronic devices often include additional functionality, like an electrocardiogram (ECG) sensor, which can detect a user's heart rate when the user contacts the user input control (e.g., the crown of a smartwatch). In many cases, when measuring an electrical signal of a user via an electrode in contact with a user's skin (e.g., for ECG, heart rate, etc.), greater accuracy and precision in the measurement may be obtained by reducing or eliminating contact points between the user's skin and other conductive objects (which may reduce the strength or detectability of an electrical signal by the electrode). However, contact between the user and other portions of the device, like adjacent buttons, may be hard to avoid during ECG or heart rate measurements, and thus the signal may be attenuated.

One possible solution to this problem is to fully electrically isolate adjacent or nearby buttons from the housing and/or other ground paths. However, fully electrically isolating components like buttons from the housing can cause the isolated piece of metal to become electrically charged relative to the housing, which may then result in unwanted electrostatic discharge between the button and the housing. For example, charge built up in a fully electrically isolated metal component may discharge to the housing and cause damage to other electronic components of the device and/or other temporary malfunction in the device. Built up charge may also transfer to the user and cause discomfort.

A button assembly, such as described herein, includes a button portion that includes an intermediate structure positioned between a cap of the button portion and a base of the button portion. This intermediate structure is bonded to the cap and the button to form an integral button portion, and electrically isolates the cap from the base, which may be conductively coupled to the housing of the device and therefore at the same electrical potential (e.g., system ground) of the housing. An electrical component may electrically couple the cap to the base, and may be encapsulated (at least partially) within the intermediate structure. As described herein, the properties and/or parameters of the electrical component may define the electrical states and/or conditions under which current can flow between the cap and the base.

For example, the electrical component may be a diode, such as a transient-voltage-suppression (TVS) diode. In this example, the TVS diode electrically isolates the cap from the base (and thus the housing) under certain voltage ranges, such as the range of voltage signals detected on a user's skin during an ECG measurement. In other situations, such as abnormal voltage conditions where electrostatic discharge is likely to occur between the button cap and the housing, the TVS diode conducts current from the cap to the housing (e.g., via the base that is conductively coupled to the housing). In this configuration, the TVS diode is a static connection with high reliability and does not take up additional space within the device. Furthermore, due to the positioning of the intermediate structure and the TVS diode between the cap and the base, the layered configuration of the button structure is not visible to the user, and the dimensions of the button can remain compact despite the integration of the electrical component. More generally, a signal (e.g., for an ECG measurement) is not attenuated due to contact of a user's skin to other button assemblies or user input controls, such as described herein.

While a TVS diode may be used in a layered button to selectively conductively couple the cap to the base, in other examples, other electrical components may be included in the intermediate structure. For example, the electrical component may be a printed circuit board (PCB). The PCB may include multiple electrical components, such as diodes, fuses, sensors, and the like. The PCB may be operably coupled to the housing of the electronic device or to other electrical components within the device and may be used for space-savings purposes, or to position electrical components close to a user interface surface of a button (e.g., for sensing functions). In other cases, the electrical component may be a fuse, a capacitor, a switch, or other suitable electronic components configured to selectively conduct electricity or perform any other applicable function.

In some cases, electrical components may be incorporated in intermediate structures of a device, such as an antenna split of the device (e.g., a nonconductive member positioned between two conductive members to conductively isolate at least portions of the conductive members). In this example, the electrical component may include a switch to affect the resonance or other property of the antenna. In other examples, electrical components may be positioned along an antenna split to affect one or more electrical properties of the antenna (or to provide other device functionality) while providing space-savings for the device compared to electrical components positioned internal to the housing.

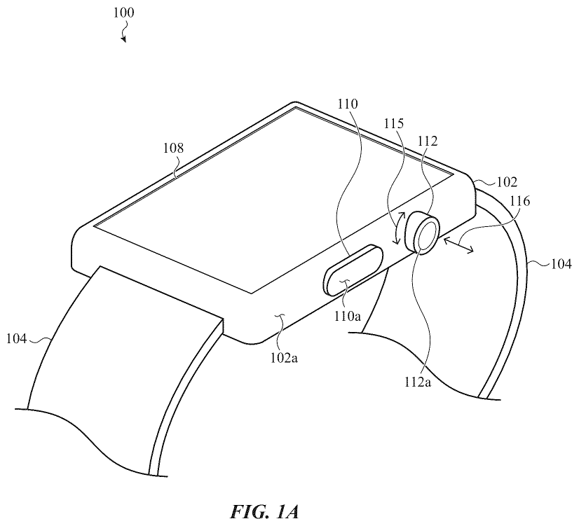

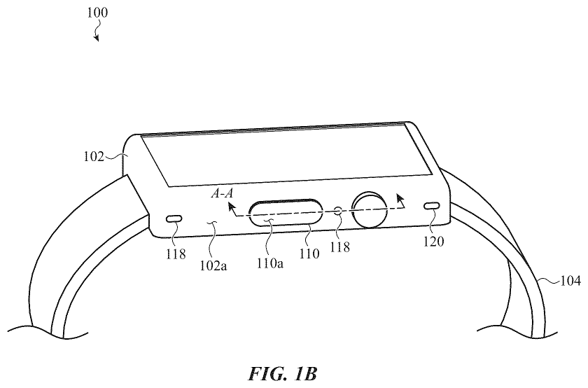

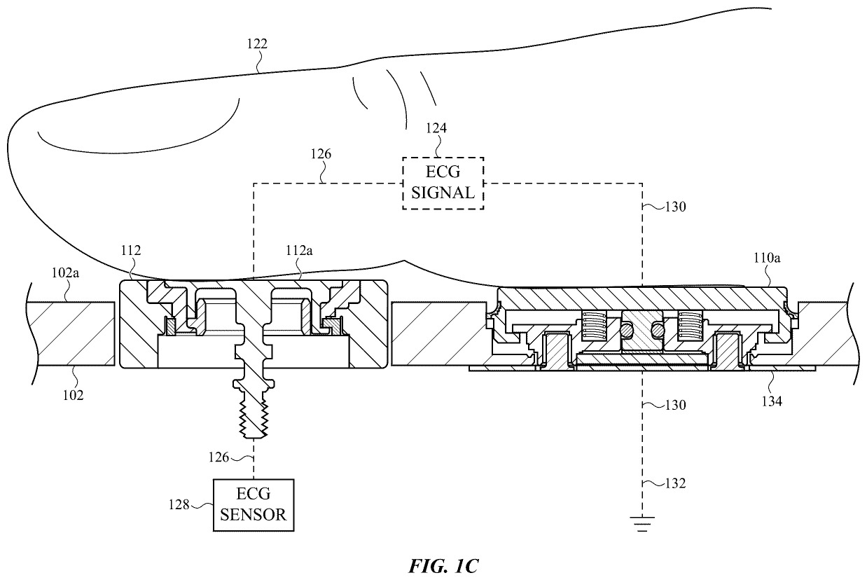

These foregoing and other embodiments are discussed below with reference to FIGS. 1A-7. However, those skilled in the art will readily appreciate that the detailed description given herein with respect to these figures is for explanation only and should not be construed as limiting.

FIG. 1A depicts a perspective view of an example electronic device 100 (or device 100) which may include a button assembly with an intermediate structure positioned between two metal portions, such as described herein. In some cases, the device 100 is a watch. In other cases, the user input control with molded portions may be incorporated into electronic devices include phones, tablets, laptops, AR/VR headsets, headphones, digital media players, and the like.

The device 100 may include a housing 102. The housing 102 may be configured to house internal components of the device, including batteries, processors, sensors, and the like. In some cases, the housing is formed from a metal, such as titanium, aluminum, steel, or any alloys or combination of materials, as may be known to one of skill in the art. In some examples, the housing is formed from ceramic, glass, polymers, and the like. The housing 102 may be a monolithic piece or may assembled from multiple parts using any suitable method. The housing may include openings and/or recesses that receive and/or secure user input controls and/or electronic components to the device 100.

A display 108 may be positioned within the housing 102. A cover may be positioned over the display. The cover may be glass, sapphire, polymer, or any suitable material, as may be known to one of skill in the art. More generally, the display may be a liquid crystal display (LCD), an organic light emitting diode display (OLED), or any suitable display technology. The display 108 outputs a graphical user interface of the device and may include other sensors, such as a fingerprint sensor, touch sensors, force sensors, and the like. The touch and/or force sensors may detect various types of user interactions including swipes, taps, and other gestures.

The device 100 may also include a wristband 104 that secures the device 100 to a user's wrist. In some cases, the wristband 104 is detachably coupled to a recess or other feature of the housing 102. In some cases, the coupling portion of the wristband 104 may be formed from the same material as the housing 102. In other examples, the wristband 104 is formed from other materials to provide a visually-distinct appearance.

The housing 102 may define an external side surface 102a along which various user input controls may be positioned. For example, the device 100 includes a side button 110 and a crown 112 positioned along (and which may partially protrude from) the external side surface 102a. The button 110 may be configured to be translated inward in response to a user input, and may be programmable such that the user can define a particular function that is controlled by the button. In some examples, at least a portion of a cap of the button 110 (e.g., which defines an external user input surface 110a of the button 110) protrudes from the external side surface 102a of the housing.

The crown 112 may protrude from the external side surface 102a of the housing 102. In some examples, at least a portion of the crown 112 is external to the housing. The crown 112 may define a generally round shape with texture, knurling, grooves, or other patterns that facilitate gripping of the crown (e.g., during rotation of the crown). In some cases, the crown includes a variety of inputs through which users can interact. For example, a user may rotate the crown 112 (interaction 115) and/or may translate the crown 112 (interaction 116) to zoom, scroll, rotate, select, or otherwise change the user interface of the display 108. In some cases, rotation of the crown 112 may be detected via self-mixing interferometry or other suitable methods as may be known to one of skill in the art.

In some examples, the crown 112 can receive biometric signals from a user. For example, the crown may be coupled to biometric sensing circuitry or include or define conductive paths to biometric circuitry within the device 100. More particularly, the crown 112 may define a user input surface 112a through which biometric signals can be received. For example, the device 100 may receive heart rate and/or ECG signals via a user contacts the crown 112 at the user input surface 112a. Specifically, the sensors may receive the signals when the user opens an application or otherwise activates the function, in some examples. More generally, the user input surface 112a may be a conductive surface (e.g., formed from a metal or similar materials as the housing) that is coupled to biometric sensors. When used to conductively couple to a user's skin for detecting signals (e.g., voltage signals), the user input surface 112a may be referred to as an electrode.

FIG. 1B shows a side perspective view of the device 100. As explained above, a device 100, such as an electronic watch, may have limited space for user input controls, such as buttons and crowns. Accordingly, as shown in FIG. 1B, the user input controls may be positioned in a central region of the side surface 102a of the device for better user access. The device 100 may additionally include ports for microphones 118, depth/water sensors 120, and the like along the side surface 102a.

FIG. 1C shows a cross-sectional view along line A-A of FIG. 1B illustrating how a user's finger may contact the crown 112 (having a physiological sensor) and adjacent buttons 110 during certain use conditions of the device 100. For example, when a user's finger 122 contacts the crown 112 (e.g., so that the device 100 can measure a physiological signal via the crown 112), the user's finger 122 may contact the button 110. In some cases, the biometric sensor may be an electrocardiogram sensor (ECG) that receives an ECG or voltage signal 124 via the electrical connection formed from the user's contact with the user input surface 110a. The ECG signal 124 is transmitted via electrical path 126 through the crown 112 and to the ECG sensor 128. However, when the user's finger 122 also contacts the button 110, which is conductively coupled to the device housing or other system ground, an additional electrical path 130 may be formed. Electrical path 130 travels from the user's skin contacting surface 110a to ground 132. The alternative current path (electrical path 130) may result in the signal that would otherwise travel via electrical path 126 being attenuated or otherwise reduced in intensity or detectability. In turn, the ECG sensor may not receive a sufficiently strong signal (e.g., a signal with a sufficiently high signal to noise ratio) for an accurate measurement.

In some examples, the button 110 is electrically coupled to the housing 102 via a coupler 134 (e.g., both in a pressed and a default state), thereby grounding the button (e.g., conductively coupling the button 110 to a ground plane). As explained above, electrically isolating the button (e.g., by applying isolating coatings to the button) may cause charge to build up in the button 110, which may then discharge to the housing, causing an electrical surge with respect to other electrical components in the device 100. Accordingly, described herein are button assemblies that selectively electrically isolate the button (or a cap of the button) so that signals are not unduly attenuated, while also limiting detrimental charge build-up on the button. While FIG. 1C illustrates an example where a user's finger is simultaneously contacting the button and the crown, this figure is generally representative of any scenario in which a user's finger contacts multiple components, where doing so may be detrimental to a sensing (or other) function that is facilitated by the contact. For example, in some cases, a device may include an ECG or other sensing electrode or surface that is not on a crown (e.g., an electrode coupled to or defined by a housing, or coupled to or defined by a button, etc.). The concepts described herein may be used to help control the electrical effects of multiple contacts in such other example scenarios.

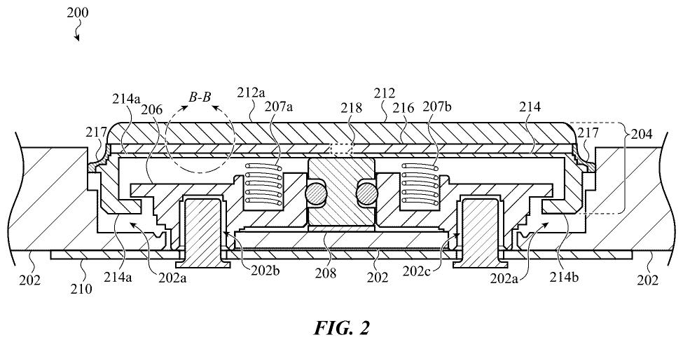

A button assembly, such as described herein, may include a button portion with an intermediate structure positioned (e.g., molded) between metal members. The intermediate structure conductively isolates the metal members so that a signal for a physiological measurement (e.g., ECG, heart rate) or other signals are not attenuated due to grounding via the button assembly. FIG. 2 shows a partial cross-sectional view of a button assembly 200. The button assembly 200 may correspond to button 110 of FIGS. 1A-1C.

The button assembly 200 may be positioned at least partially within an opening defined by the housing 202. In some cases, the opening of the housing is or includes a through hole. In other embodiments the housing 202 defines a first cavity 202a in which a substantial portion of the button assembly is positioned and additional openings 202b and 202c, through which portions of the button assembly extend which, in turn, secures the button assembly 200 to the housing 202.

The button assembly may include a button portion 204 that is configured to translate when a user presses on it. The button portion 204 may have a default state (e.g., an undepressed state) where a bracket 206 applies a biasing force towards the exterior of the device (e.g., via springs 207a and 207b, or other biasing members). In a pressed state (e.g., when a user presses down on the button portion 204), the button portion 204 may move towards the inside of the housing. The button assembly 200 may include a tactile feedback component, such as a dome switch 208, that provides a tactile response to the user when the button portion is pressed. While a dome switch 208 is described, other haptic feedback systems are also envisioned.

The button portion 204 is movably coupled to the bracket 206. The button portion 204 may include flanged or bracketed portions that prevent the button portion 204 from detaching from the bracket 206. Similarly, portions of the button portion, such as springs 207a and 207b may be coupled to the button portion 204.

In some cases, the bracket 206 is fixedly coupled to the housing 202 via a coupler 210. The coupler 210 may be metal or other conductive material. Due to this configuration (e.g., the conductive coupler 210 contacting the housing 202 and the bracket 206), the button portion 204 is also conductively coupled to the housing 202.

The button portion 204 may include a cap 212, a base 214, an intermediate structure 216, a gasket 217, and an electrical component 218. The cap 212, the base 214, the intermediate structure 216, the gasket 217, and the electrical component 218 may be fixedly coupled to each other such that the button portion 204 forms a unitary piece assembled to form part of the button assembly 200. As noted, in some examples, the cap 212 and the base 214 are formed from a metal, such as titanium, steel, aluminum, titanium alloys, steel alloys, aluminum alloys, or any other metals or combination of metals or other conductive materials. While the instant description refers to the cap 212 and the base 214 as a metal cap and metal base, respectively, it will be understood that the description is not limited to caps and bases of metal materials, but may include other conductive materials as well (or components that include conductive materials).

The metal cap 212 defines a user input surface 212a that is an externally-facing surface which the user touches or otherwise interacts with (e.g., when pushing the button portion 204). In some cases, the metal cap 212 may be fully external to the housing in a default state of the button portion 204. In some examples, at least a portion of a side portion of the metal cap 212 may extend into the cavity 202a of the housing 202.

The metal base 214 may be positioned at least partially, and optionally fully within the cavity 202a. More specifically, the metal base 214 may be recessed with respect to an external side surface of the housing 202. In some examples, the metal base 214 is the piece which secures the button portion 204 to the bracket 206. For example, the metal base 214 may include brackets or other flanged portions 214b that latch to the bracket 206 to prevent motion towards the outside of the housing 202 (and define the fully extended, unactuated position of the button portion 204). The metal base 214 may be movably coupled with respect to both the housing 202 and the bracket 206 such that the metal base 214 and the metal cap 212 can move collectively when a user presses the button portion 204.

The button portion 204 may further include an intermediate structure 216. The intermediate structure 216 is positioned between the metal cap 212 and the metal base 214. Unlike the metal cap 212 and the metal base 214, the intermediate structure 216 may be formed from a dielectric material, such as a polymer. The intermediate structure 216 may be formed by a molding process, such as overmolding, insert molding, injection molding, low-injection pressure overmolding (LIPO), or the like.

To form the intermediate structure 216, the metal cap 212 and the metal base 214 may be positioned within a mold defining a cavity. Within the mold, the metal cap 212 and the metal base 214 define a spacing between each other in which the intermediate structure will be formed. A polymer (e.g., a resin) is injected or otherwise introduced into the mold, such that the polymer flows between the metal cap 212 and the metal base 214. In some cases, the polymer may be under high temperature or high pressure, or it may be under low pressure (e.g., using a LIPO process). Regardless of the pressure involved, the polymer is allowed to harden, which creates a sandwiched structure of the button portion 204. This sandwiched structure forms a structure having high resistance and/or impedance between the cap 212 and the base 214. Due to the high resistance and/or impedance (e.g., due to the insulating and/or dielectric properties of the intermediate structure 216), the intermediate structure effectively electrically isolates the metal cap 212 from the metal base 214. Due to the molding process and other optional surface preparation steps of the metal cap 212 and the metal base 214, the resulting intermediate structure 216 bonds to a surface of the metal cap 212 (e.g., opposite the user-input surface 212a) and to a surface of the metal base 214 (e.g., surface 214a that faces the metal cap 212). Thus, the intermediate structure 216 is bonded with the metal cap 212 and the metal base. In some examples, the intermediate structure 216 is machined or further processed to create a smooth, continuous side surface between the metal cap 212, the intermediate structure 216, and the metal base 214. For example, the three portions are coupled to resemble a single, monolithic piece.

In some cases, the button portion 204 includes a gasket 217. The gasket 217 may be configured to keep out contaminants and/or to act as a bumper, wiper, or interface between the button portion 204 and the housing 202. In some examples, the gasket 217 is positioned around a periphery of the metal cap 212, the intermediate structure 216, and/or the metal base 214. In some cases, the gasket 217 is positioned around a periphery of the intermediate structure 216 and the metal base 214 such that the gasket 217 conceals the intermediate structure 216 from view. In this configuration, a user inspecting the button portion 204 may perceive the button portion 204 as a monolithic piece rather than multiple pieces coupled together via an intermediate structure of a different material. The gasket 217, in some cases, may be positioned within the cavity 202a of the housing 202 and thus may not be visible when the button assembly 200 is mounted to the housing 202.

More generally, the gasket 217 may wrap around the entire circumference of the button portion 204 and may contact the housing 202, thereby creating a seal between the housing 202 and the button portion 204. In some cases, in the unpressed position, the gasket 217 may be, at least partially, deformed to create a seal. In the pressed position, the gasket 217 may move downwards and not contact the housing 202.

In some cases, an electrical component 218 is embedded within the button portion 204. More specifically, the electrical component 218 may be at least partially encapsulated within the intermediate structure 216. The electrical component 218 may be electrically coupled to the metal cap 212 and the metal base 214 (e.g., via soldering, welding, fastening, and the like). Once the electrical component 218 is coupled to the metal cap 212 and the metal base 214, the intermediate structure 216 is formed around the electrical component 218 and between the cap and base, thereby coupling and at least partially encapsulating the electrical component 218 within the intermediate structure 216. In this configuration, an electrical circuit may be formed between the metal cap 212 and the metal base 214. In some cases, the electrical component 218 can control the flow of current between the metal cap 212 and the metal base 214. For example, depending on the properties of the electrical component 218, the metal cap 212 may be grounded under certain states (e.g., conductively coupled to the metal base 214 and thus the housing) and may be electrically isolated from the housing under other states. As another example, under certain conditions, such as a high-frequency AC current, the electrical component 218 may have a low impedance, thereby allowing current to flow between the cap 212 and the base 214. Under other conditions, such as low-frequency AC current, the electrical component may have a high impedance, thereby affecting the current flow (e.g., effectively isolate, attenuate) between the cap 212 and the base 214.

A benefit of this configuration is that the electrical component 218 is within the button portion 204 and thus does not take up additional, valuable space within the device. Also, the connection between the metal cap 212 and the metal base 214 is static and is thus less susceptible to damage than a moving or flexible connection, such as a wire or flexible circuit element (e.g., due to the translation of the button assembly 200 flexing or deforming a flexible connection).

More generally, the electrical properties of the intermediate structure 216 increases the resistance and/or reactance to current flow between the cap 212 and the base 214. Thus, the intermediate structure may effectively electrically isolate the cap 212 from the base 214. In some cases, the extent or properties of the electrical isolation may depend at least in part on the frequency of the current (e.g., at high frequencies, some current may be conducted).

The electrical component 218 may provide an electrical path between these pieces (e.g., the cap 212 and the base 214), such as to provide grounding and/or isolating functions between the pieces. The electrical component 218 may have different electrical properties and/or impedance from the intermediate structure 216. These electrical properties may change under different states and/or voltage/current conditions.

In some examples, the button portion 204 may not have an electrical component 218, and the metal cap 212 and the metal base 214 may be electrically decoupled (e.g., the intermediate structure 216 fills the entire space between the metal cap and the metal base 214 and thus the electrical properties are determined by the material and dimensions of the intermediate structure).

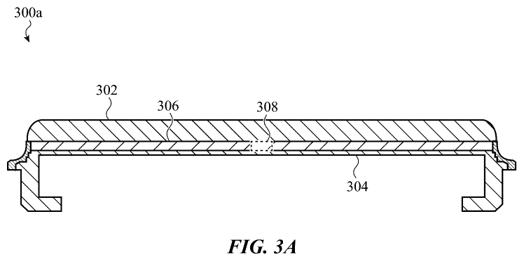

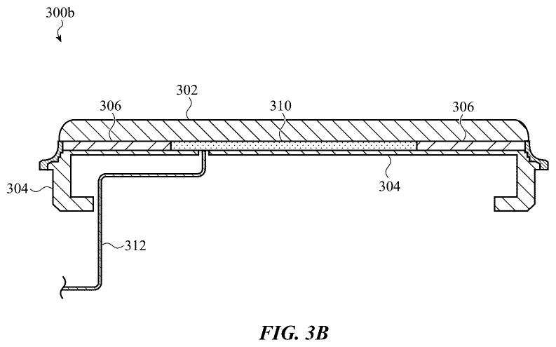

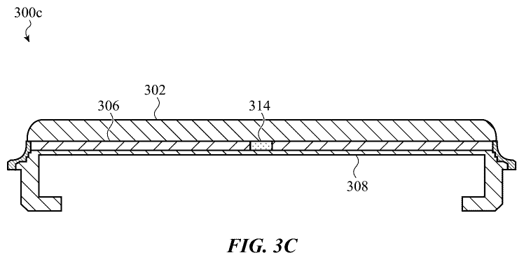

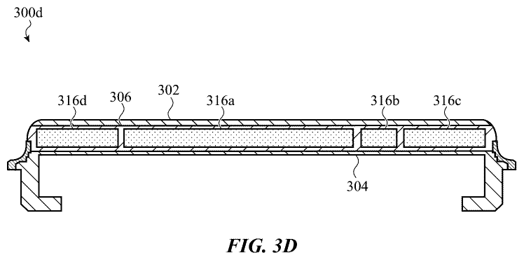

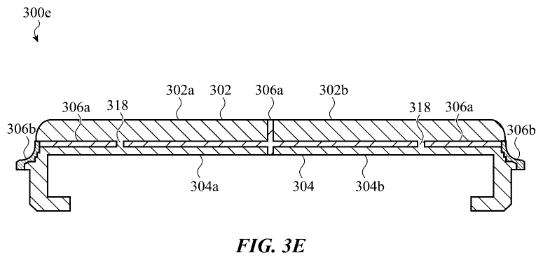

In some examples, the electrical component 218 has different electrical impedance and/or resistance values (between the cap 212 and the base 214) under different conditions. For example, the electrical component 218 may selectively electrically isolate the cap 212 and the base 214 under certain electrical conditions while conducting electricity under different electrical conditions. In some cases, other electrical components may also be used to perform the same or other electrical functions. FIGS. 3A-3D show cross-sectional views of button portions 300a-300d which incorporate various electrical components. The button portions 300a-300d may correspond to the button portion 204, including its components and method of manufacturing explained above.

As shown in FIG. 3A, a button portion 300a may include an electrical component 308 which may correspond to a transient-voltage-suppression (TVS) diode or an electrostatic discharge (ESD) protection diode (hereinafter TVS diode). A TVS diode may be configured to allow current flow under certain states (e.g., voltages above and below a threshold, certain electrical frequencies) while suppressing and/or isolating current flow in other conditions (e.g., voltages within a range, other electrical frequencies). In this configuration, when an ECG measurement is taken, the voltage and/or current (or other electrical value) between the cap and the base may be within the range where current does not flow from the metal cap 302 to the metal base 304. For example, the voltage at the user's skin when a user simultaneously contacts the crown and the button portion 300a is within a range in which the TVS diode effectively isolates the cap 302 from the housing, and thus the signal to the crown is not attenuated or drained by the button portion 300a. In other examples, the ECG measurement may correspond to a lower electrical frequency relative to the ESD discharge frequencies. The TVS diode may be configured to conduct electricity when a threshold is exceeded.

More generally, in some examples, the TVS diode may be a unidirectional or a bidirectional TVS diode. In other examples, the electrical component 308 may be other types of diodes, including a Zener diode, a variable capacitance diode, a Schottky barrier diode, and the like.

The TVS diode (e.g., electrical component 308) may include two pins or pads. A first pin is coupled to the metal cap 302 (e.g., via soldering, welding, fastening, and the like) and the second pin is coupled to the metal base 304, in some examples. The intermediate structure 306 may be formed around the TVS diode to at least partially encapsulate the diode and to effectively electrically isolate the cap 302 and the base 304 from each other (e.g., outside of the TVS diode interface). In some cases, the metal cap 302 and the metal base 304 may include protruding portions and/or receding portions from the surface where the pins of the TVS diode are coupled to facilitate the electrical connection during manufacturing.

FIG. 3A also generally illustrates a button portion configuration in which any electrical component may be positioned between a button cap and a base, and at least partially encapsulated in an intermediate structure (which may be an electrical insulator). Accordingly, the electrical component 308 may represent other electrical components and combinations thereof, including but not limited to circuit boards, capacitors, resistors, processors, diodes, integrated circuits, sensors, sensing elements, electrodes, and the like.

FIG. 3B shows another variation of a button portion 300b. In this view, the electrical component may be a printed circuit board (PCB) 310. The PCB may include one or more electrical components and/or electrical sensors mounted to a substrate. The PCB may be electrically coupled to the housing via connection 312. Connection 312 may be a flexible connection configured to translate with the button portion 300b when it is pressed and/or in a default condition. In other examples, the connection 312 may be omitted, and the PCB may be electrically coupled only to the cap and the base.

The PCB may include electrical components, like the TVS diode described above, that conductively couples the cap 302 to the base 304 under an avalanche voltage condition (e.g., at voltages that may otherwise result in electrostatic discharge) and effectively isolates the cap from the base under “normal” voltage ranges (e.g., voltages less than the avalanche voltage). In some cases, the PCB may additionally include a plurality of electrical components, electrical sensors, and the like which are not conductively coupled to the cap 302, or to the base 304, or to neither the cap 302 nor the base 304. These components and sensors may be part of other functionalities or features of the device. In this configuration, the cavity of the button portion 300b that is defined by the spacing between the cap 302 and the base 304 may be used for space-saving purpose or to add additional functionality to the device without occupying space inside the device.

As described above as to the button portion 300a, the intermediate structure 306 may be formed around the PCB 310. In some examples, depending on the electrical components or sensors mounted in the PCB, a LIPO process may be employed to prevent damaging the electrical components. In this example, the PCB 310 may be encapsulated within the intermediate structure 306. In other examples, the intermediate structure 306 may be formed around a cavity and the PCB 310 may then be inserted within the cavity and coupled to the device via connection 312. In this example, the metal base 304 may define an opening to insert and/or connect the PCB 310.

FIG. 3C shows a variation of a button portion 300c. In this configuration, the button portion 300b may include an electrical component 314 which may be a fuse. Similar to the button portion 300a variation, the fuse may electrically isolate the metal cap 302 from the metal base 304. In some examples, the fuse may be a polyfuse formed from a polymer mixture, configured to allow current flow under certain conditions (e.g., under a voltage range) due to polymeric chains allowing the flow of electricity. In a condition of high current or voltage flow, the fuse may break the electrical flow when a temperature rises above a threshold. In some cases, the electrical component 314 may be included in addition to electrical components described above. In some cases, fuses may be employed where it is desirable to maintain a conductive coupling between the cap and the base at low voltages and/or current conditions, and break the conductive coupling at high voltages and/or current conditions.

FIG. 3D shows another variation of a button portion 300d. In this variation, multiple electrical components 316a-d may be encapsulated within the intermediate structure 306. For example, the multiple electrical components 316a-d may be a TVS diode, a PCB, a fuse, a capacitor, a battery, a resistor and/or heating element, sensors, and the like. In some examples, the electrical components 316 may be conductively coupled to the cap 302 and the base 304. In other examples, electrical component (e.g., electrical component 316b) may be coupled to base 304 and electrically isolated from the cap. For example, electrical component 316b may be a component operably coupled to the device and positioned within the button as a space-saving configuration. More generally, multiple electrical components 316a-d may be positioned within the button without taking up additional space within the device. In some cases, due to the manufacturing of the button portion 300d, the electrical components within the device may add an additional layer of protection for the electronic components and help prevent tampering with (e.g., removing) the electronic components from the device. For example, anti-theft technology may be incorporated within the button portion 300d, for example.

FIG. 3E shows a variation of a button portion 300e. In this variation, the button portion 300e includes more than one intermediate portion (e.g., distinct polymer elements disposed in different regions of the button portion). For example, the button portion 300e may include an intermediate structure 306a and a gasket portion 306b. An interface member 318 may be positioned (e.g., encapsulated) within the intermediate structure 306a and/or positioned between the cap 302 and the base 304.

In some cases, the button portion may include multiple metal cap pieces and multiple metal base pieces that together ultimately define the complete structure of the button portion. In this example, the intermediate structure 306a may be formed between the metal cap pieces and the metal base pieces, thereby forming a button portion 300e that is split left and right of the page (FIG. 3E). In this example, the metal cap 302 may be split in a left cap 302a and a right cap 302b. Similarly, the metal base 304 may be split in a left base 304a and a right base 304b. While the foregoing is described in terms of left and right, more generally, the example is directed to multiple cap pieces split and separated by an intermediate structure 306. Each side of the button portion 300e may define a different electrical path from its respective cap piece, through each of the interface members 318, and through a respective base piece. In this configuration, two different signals may be transmitted through the button portion (e.g., signal from a respective finger in an ECG measurement). In some examples, the interface member 318 may be an electrical component, such as a TVS diode, a capacitor, a fuse, and the like. In some examples, the interface member 318 may be contiguous with the cap and the base (e.g., the cap, base, and interface member may be segments of a single piece of material). In other examples, the interface member 318 is an electrically coupling member between the cap and the base.

In some cases, the intermediate structure 306a and the gasket 306b may be formed integrally using an injection molding process. For instance, the intermediate structure 306a may be made from a first polymer material and the gasket 306b may be made from a second polymer material. In this example, the intermediate structure 306a and the gasket 306b may be formed using a two-shot injection molding process, where the intermediate portion and the gasket are formed in two phases. In the first phase, the intermediate portions internal to the button portion may be formed using a shot of polymer and allowed to harden to form a solid piece. In the second phase, the piece may be transferred to a second mold (or left in the same mold, which may include movable mold surfaces) and a second polymer may be injected to form the gasket 306b and/or other external portions of the button portion 300e. The different polymers may bond to one another and to the metal or other material surfaces of the cap and base, such that the intermediate structure(s) and the gasket are bonded in place. In some cases, both the gasket 306b and the intermediate structure 306a may be formed using a single shot process. While the two-shot and single-shot injection molding process for collectively forming the intermediate portions and the gasket are described as to FIG. 3E, this process may be applied to the examples of FIG. 3A-3D described above. In particular, in any example button described herein, the gasket may be formed from the same material as the intermediate structure or a different material, and may be formed via the same process as the intermediate structure (e.g., a single molding process), or via a secondary process (e.g., by a second molding or other forming or attachment process).

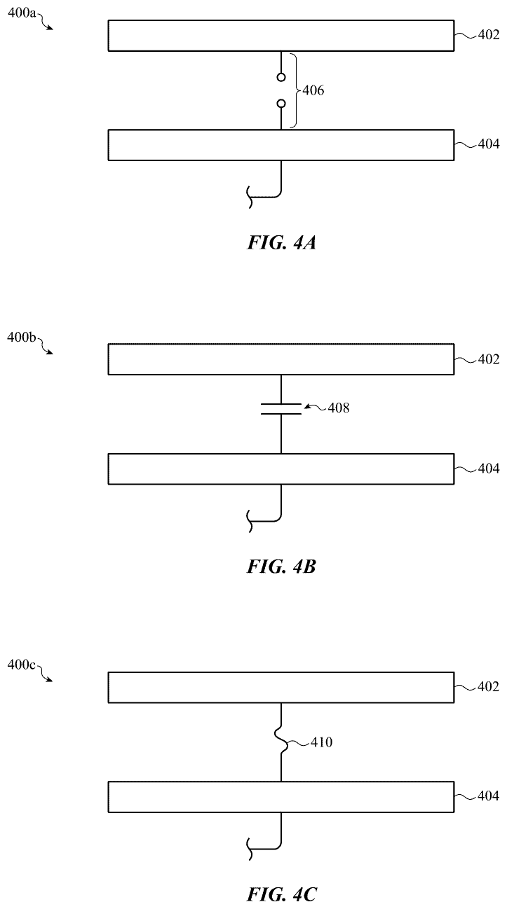

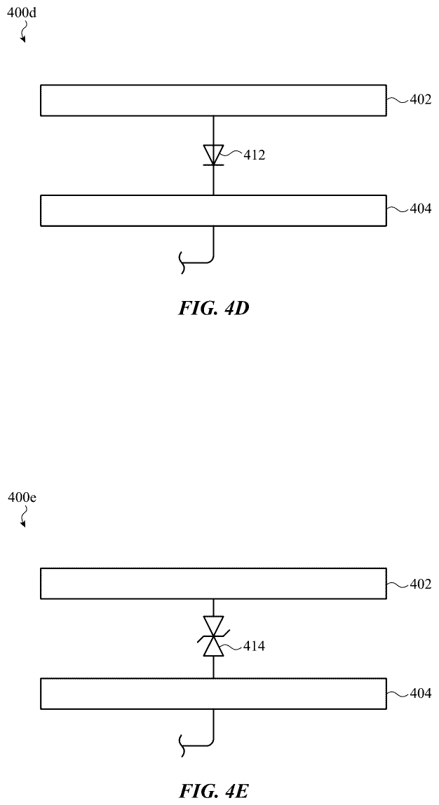

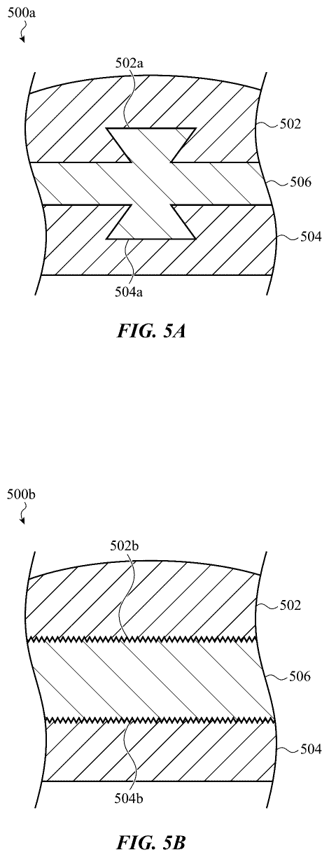

FIG. 4A-4E show example equivalent circuits that may be formed due to an electrical component between the cap and base, or simply due to the electrical properties of the cap, base, and intermediate portion (e.g., without an electrical component therebetween). In FIGS. 4A-4E, the cap 402 and the base 404 schematically represent cap and base members of a button, such as the cap 302 and the base 304, respectively. The separation or gap between the cap 402 and the base 404 may schematically represent the electrical effect of an intermediate structure, such as the intermediate structure 306. In particular, because the intermediate structures described herein may be dielectric materials (e.g., electrically insulating polymers), the cap 402 and base 404 may be electrically isolated by the intermediate structures. Of course, as described herein, the cap 402 and base 404 may be electrically coupled via other paths or components.

Returning to FIG. 4A, due to the electrical isolation between the cap 402 and the base 404, no current can flow between the cap 402 and the base 404. This equivalent circuit 400a may be achieved, for example, due a dielectric or otherwise electrically insulating intermediate structure (e.g., represented by the open circuit 406) being formed between the cap 402 and the base 404 without an electrical connection between the cap 402 and the base 404. In some examples, the button portion may include an electrical component that acts as an open circuit between the cap 402 and the base 404. In other examples, this electrical component may be a switch that creates an open circuit 406 under a first state (e.g., a voltage range, a voltage threshold, a current range, and the like). The switch may also close to define a short circuit under a second state (e.g., electrostatic discharge or other abnormal discharge conditions). In the example of FIG. 4A, the open circuit between the cap 402 and the base 404 may result in the button member ultimately defining a capacitor. In such cases, the base 404 may be conductively coupled to other circuitry of a device such that the capacitor may be used as a functional electrical component (e.g., for touch and/or presence sensing, antenna functions, etc.). The capacitance of the capacitor that is formed by the cap and base may be tuned or defined by selecting parameters such as the dielectric constant of the intermediate structure, the distance between the cap and base, and the facing areas and shapes of the cap and base.

FIG. 4B shows an example equivalent circuit 400b that includes a capacitor 408 between the cap 402 and the base 404. The capacitor 408 may be an ESD capacitor configured to absorb electrostatic discharge. In this configuration, electrical charge that may otherwise be retained by the cap 402 (e.g., due to an open circuit between the cap and the base) may be absorbed by the capacitor 408, thereby preventing or inhibiting possible surges of charge from the cap 402 to a housing of the device. In conditions where a user's finger touches the cap 402 and other user input members (e.g., a crown with an ECG electrode, or simply just an ECG electrode) simultaneously, the signal to the other user input may not be attenuated because the capacitor 408 may not ground the signal, thereby effectively isolating the cap 402 under certain voltage conditions.

In some embodiments, the capacitor 408 may be used to conduct current at certain frequencies while blocking current at other frequencies. For example, the capacitive reactance of the capacitor 408 may be inversely proportional to a frequency of an AC signal passing through capacitor 408. Thus, at low frequencies (such as those from an ECG signal), the capacitor 408 has high impedance and thus does not effectively conduct electricity. At higher frequencies, the impedance of the capacitor decreases, thereby conducting electricity.

FIG. 4C shows an example equivalent circuit 400c that includes a fuse 410. As discussed above, the fuse 410 may be any suitable fuse, such as a polyfuse, a fuse switch, or other resettable fuses. In this equivalent circuit 400c, the fuse 410 conducts current under certain conditions (e.g., operating zone of the fuse) while effectively isolating the cap 402 from the base 404 under other conditions (e.g., high currents or electrical discharges).

FIG. 4D shows an example equivalent circuit 400d that includes a diode 412. The diode 412 may be a Zener diode, a rectifier diode, or the like. The diode 412 allows current from the cap 402 to flow to the base 404 under certain conditions and may block current from flowing outside of those conditions. Due to the directionality of the diode 412, current may not flow from the base 404 to the cap 402. Moreover, the polarity of the diode may differ from that shown in FIG. 4D. In other examples, as shown in FIG. 4E, the equivalent circuit 400e may include a TVS diode 414. As discussed above, the TVS diode 414 may be part of an electrical component that couples the cap 402 to the base 404. In this example, the diode 414 may work at both positive and negative voltages.

As discussed above, an intermediate structure of a button portion may be molded between a cap and a base of the button. FIGS. 5A and 5B show example mechanical interlocks for mechanically coupling the intermediate structure to the cap and the base. FIGS. 5A-5B illustrate area B-B in FIG. 2, though this is merely one example location for such interlocks, and similar interlocks may be provided at various locations in order to aid in the mechanical coupling between the intermediate structure and other components (e.g., the cap, base, etc.).

FIG. 5A shows a detail view of an interlock example 500a. The interlocks may improve the bonding between the cap and the base to the intermediate structure by defining a mechanical engagement between the components. As depicted, a cap 502 may include a first feature 502a. Similarly, a base 504 may include a second feature 504a. The features 502a, 502b are illustrated as cavities with undercut regions (e.g., a dovetail cavity), though other features are also contemplated, such as protrusions, blind holes, through holes, posts, channels, etc.

An intermediate structure 506 engages the first feature 502a and the second feature 504a (e.g., fills the cavities), thereby mechanically coupling the intermediate structure 506 to both the cap 502 and the base 504. In some examples, the first and second features 502a and 504a may each define a flared shape along the cross-section shown in FIG. 5A. In other examples, the first and second features 502a and 504a may each define a flanged shape, a circular shape, a squared/rectangular shape, or any other shapes or combination of shapes as may be known to one of skill in the art.

FIG. 5B shows another example 500b technique for providing a secure bond between a cap and base of a button member. Here, the cap 502 and the base 504 define textured surfaces 502b, 504b, respectively, which increase the surface area between the cap 502 and the intermediate structure 506, and between the base 504 and the intermediate structure 506. Due to the textured surface, the bonding to the cap 502 and to the base 504 may be improved relative to a non-textured or smooth surface. The textured surface may be achieved using any suitable method, such as grit blasting, laser texturing, machining, and the like. In some examples, the cap 502 and the base 504 may be chemically etched in lieu of or in addition to the texturing and/or mechanical interlock features.

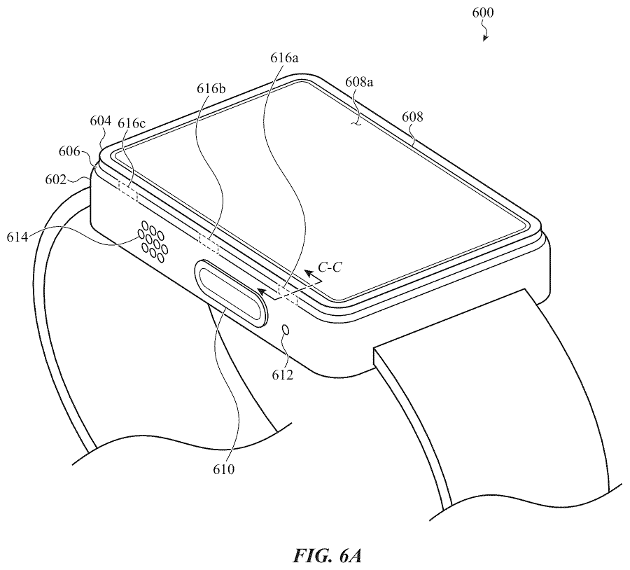

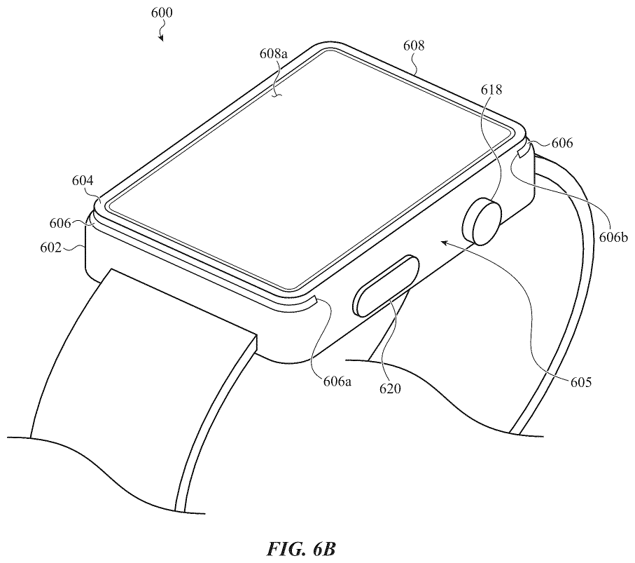

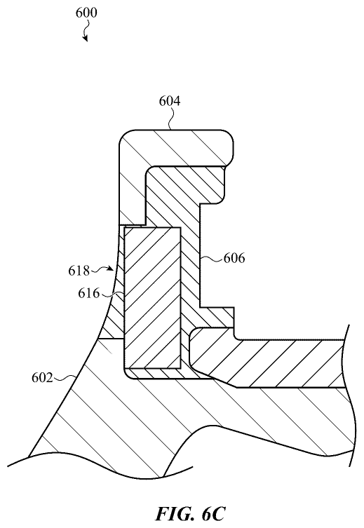

FIG. 6A-6C shows an embodiment of an electronic device that includes an electronic component embedded within a polymer structure that is positioned between portions of two conductive members. FIG. 6A shows a perspective view of a first side of an example electronic device 600. The device 600 may be an electronic watch, or other device described with respect to device 100 of FIGS. 1A-1B above. The device 600 may include a wireless communication system that includes antennas. These antennas may be resonating antenna elements in communication with the wireless communication system.

The device 600 may include a first housing member 602. The first housing member 602 may house the majority of the electronic components of the device, including a battery, optical sensor(s), speakers, microphones, and the like. In some examples, the first housing member 602 is formed from a conductive material or combination of materials, such as titanium, steel, steel alloys, aluminum, and the like. In some embodiments, the first housing member 602 includes openings and/or other features for different user inputs and/or other outputs. For example, the first housing member 602 may include an opening 612 for a microphone, openings 614 may be configured to output sound from the speakers, and button 610 may extend from an opening in the first housing portion.

The device 600 may additionally include a second housing member 604. The second housing member may be a top portion of the device and may include a display 608. The display 608 may define a display surface 608a of the device and may be at least partially surrounded by the second housing member 604. For example, a portion of the second housing member 604 and the display 608 may define a flush top surface. In some cases, the second housing portion 604 may house the resonating antenna elements of the device. For example, a portion of the second housing member 604 may define at least a portion of a radiating structure of an antenna.

The first housing member 602 and the second housing member 604 may be separated, along at least part of their respective structures, by an intermediate structure 606 which fills a gap between the first housing member 602 and the second housing member 604. The intermediate structure 606 may be formed using a molding process, such as described above, and may be polymer material. For example, the intermediate structure may be a dielectric material. In some embodiments, the intermediate portion may be flush with respect to the first and second housing members.

The device 600 may include one or more of electrical component(s) 616a-c at least partially embedded within the intermediate structure 606. The electrical components 616a-c may be spaced along the intermediate structure 606 and may be configured to affect and/or control the electrical properties of the intermediate structure 606 (and/or the housing members, portions of which may act as radiating members of an antenna) and thereby affecting the properties of the antenna.

FIG. 6B shows a perspective view of a second side of a device 600. In the example shown in FIG. 6B, the first and second housing portions may be continuous and/or electrically coupled to each other. More specifically, as depicted, the first housing member 602 and the second housing member 604 may be coupled at region 605 of the device 600. In this example, first and second housing members 602 and 604 define a slot in which the intermediate structure 606 is formed. In this configuration, the intermediate portion may define ends 606a and 606b where the intermediate structure terminates. (In some examples, the first and second housing members are formed from separate components, and are not conductively coupled at region 605.)

At region 605, additional user controls, like a crown 618 and a button 620 may be positioned. In some embodiments, the first housing member 602 may define protrusions and/or other features to accommodate the crown 618 and the button 620. For example, the first housing member 602 may define a protrusion at region 605 that includes a spacing between the first housing member and internal cavities of the housing in which the crown 618 and the button 620 can be externally placed with respect to internal cavities.

FIG. 6C shows a partial cross-sectional view along line C-C of FIG. 6A. As depicted, an electrical component 616 may be embedded within the intermediate structure 606 which, in turn, is sandwiched between portions of the first housing member 602 and the second housing member 604. The electrical component 616 may be electrically coupled to the first housing member 602, or to the second housing member 604, or to both the first and the second housing member 602 and 604. In some examples, the first housing member 602, the second housing member 604, and the intermediate structure 606 cooperate to define an external surface 618 of the device 600. The intermediate structure 606 may occlude the electrical component 616 from view. In some examples, the electrical component 616 may include LEDs that emit light through the intermediate structure 606, thereby creating subtle edge lighting for the device and/or providing indicators to the user, such as a battery indicator.

In some cases, the electrical component 616 may be a switch that can operate as a ground switch for the wireless communication system. When the electrical component 616 is a switch, the switch may be used to modify a resonance of the antenna of the device. For example, under some conditions, the switch may be closed, thereby defining a different conductive path between the first and second housing members as compared to when the switch is open (which may ultimately be used to change or modify the resonance length of the antenna, as described herein). In some examples, depending on the target resonance of the antenna, different and/or multiple electrical components 616 may switch on or off to achieve different resonances.

In some examples, the electrical component 616 may be a conductive element that alters the resonance of the antenna (e.g., by changing the length of a conductive path of a resonating element for an antenna). In other examples, the electrical component 616 may be a flex circuit, a TVS diode, a resistor, a capacitor, or any other suitable electrical component, such as those described with respect to FIGS. 4A-4E. While the electrical component 616 is discussed in the context of affecting an antenna element within the device, the electrical component 616 may represent any electronic component of the device, and may be positioned in the intermediate structure 606 for space saving purposes (such as a flex circuit operably coupled to the processor of the device, a sensor, a microphone, a speaker, etc.).

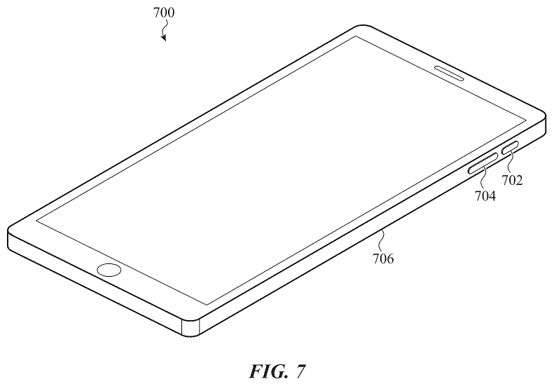

While the above examples are described in the context of an electronic watch (e.g., device 100), the button assembly and the housing configurations described herein may be implemented in other electronic devices as well. For example, FIG. 7 shows a perspective view of an example device 700 that includes a first user input control 702 (e.g., a button, fingerprint sensor, electrode, switch, etc.) and a second user input control 704 (e.g., a button) along a side of a housing 706 of the device 700. As depicted, the first and second user input controls 702 and 704 may be proximate to each other and thus electrical isolation under certain states is desired. For example, simultaneous contact of a user's finger with controls 702 and 704 may affect a signal received by the first user control 702. User control 704 may be configured to isolate the cap under normal conditions and ground the cap under abnormal discharge conditions. The button and housing concepts described herein may be used with other devices as well, such as smart phones, tablet computers, laptop computers, head-mounted displays, game controllers, remote controls, and the like.

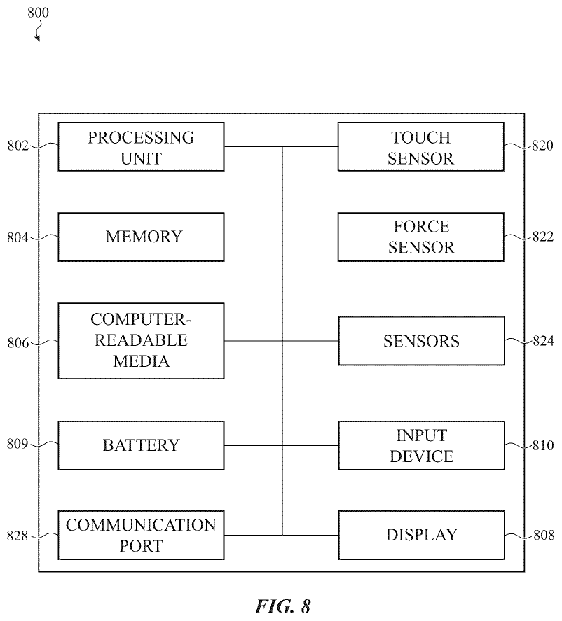

FIG. 8 depicts an example schematic diagram of an electronic device 800. The device 800 of FIG. 8 may correspond to the wearable electronic device 100 shown in FIGS. 1A-1B (or any other wearable electronic device described herein). To the extent that multiple functionalities, operations, and structures are disclosed as being part of, incorporated into, or performed by the device 800, it should be understood that various examples may omit any or all such described functionalities, operations, and structures. Thus, different examples of the device 800 may have some, none, or all of the various capabilities, apparatuses, physical features, modes, and operating parameters discussed herein.

As shown in FIG. 8, a device 800 includes a processing unit 802 operatively connected to computer memory 804 and/or computer-readable media 806. The processing unit 802 may be operatively connected to the memory 804 and computer-readable media 806 components via an electronic bus or bridge. The processing unit 802 may include one or more computer processors or microcontrollers that are configured to perform operations in response to computer-readable instructions. The processing unit 802 may include the central processing unit (CPU) of the device. Additionally or alternatively, the processing unit 802 may include other processors within the device including application specific integrated chips (ASIC) and other microcontroller devices.

The memory 804 may include a variety of types of non-transitory computer-readable storage media, including, for example, read access memory (RAM), read-only memory (ROM), erasable programmable memory (e.g., EPROM and EEPROM), or flash memory. The memory 804 is configured to store computer-readable instructions, sensor values, and other persistent software elements. Computer-readable media 806 also includes a variety of types of non-transitory computer-readable storage media including, for example, a hard-drive storage device, a solid-state storage device, a portable magnetic storage device, or other similar device. The computer-readable media 806 may also be configured to store computer-readable instructions, sensor values, and other persistent software elements.

In this example, the processing unit 802 is operable to read computer-readable instructions stored on the memory 804 and/or computer-readable media 806. The computer-readable instructions may adapt the processing unit 802 to perform the operations or functions described herein. In particular, the processing unit 802, the memory 804, and/or the computer-readable media 806 may be configured to cooperate with a sensor 824 (e.g., a rotation sensor that senses rotation of a crown component) to control the operation of a device in response to an input applied to a crown of a device (e.g., the crown 112 or any other crown described herein). The computer-readable instructions may be provided as a computer-program product, software application, or the like.

As shown in FIG. 8, the device 800 also includes a display 808. The display 808 may include a liquid-crystal display (LCD), organic light emitting diode (OLED) display, light emitting diode (LED) display, or the like. If the display 808 is an LCD, the display 808 may also include a backlight component that can be controlled to provide variable levels of display brightness. If the display 808 is an OLED or LED type display, the brightness of the display 808 may be controlled by modifying the electrical signals that are provided to display elements. The display 808 may correspond to any of the displays shown or described herein.

The device 800 may also include a battery 809 that is configured to provide electrical power to the components of the device 800. The battery 809 may include one or more power storage cells that are linked together to provide an internal supply of electrical power. The battery 809 may be operatively coupled to power management circuitry that is configured to provide appropriate voltage and power levels for individual components or groups of components within the device 800. The battery 809, via power management circuitry, may be configured to receive power from an external source, such as an AC power outlet. The battery 809 may store received power so that the device 800 may operate without connection to an external power source for an extended period of time, which may range from several hours to several days.

In some examples, the device 800 includes one or more input devices 810. An input device 810 is a device that is configured to receive user input. The one or more input devices 810 may include, for example, a crown input system (e.g., any of the crowns described herein), a push button, a touch-activated button, a keyboard, a keypad, or the like (including any combination of these or other components). In some examples, the input device 810 may provide a dedicated or primary function, including, for example, a power button, volume buttons, home buttons, scroll wheels, and camera buttons.

The device 800 may also include one or more sensors 824. The sensors 824 may detect inputs provided by a user to a crown of the device (e.g., the crown 112 or any other crown described herein). The sensors 824 may include sensing circuitry and other sensing components that facilitate sensing of rotational motion of a crown, as well as sensing circuitry and other sensing components (optionally including a switch) that facilitate sensing of translational and/or axial motion of the crown (or axial force applied to the crown). The sensors 824 may include components such as an optical sensing unit, a tactile or dome switch, or any other suitable components or sensors that may be used to provide the sensing functions described herein. The sensors 824 may also include a biometric sensor, such as a heart rate sensor, electrocardiograph sensor, temperature sensor, or any other sensor that conductively couples to the user and/or to the external environment through a crown input system, as described herein. In cases where the sensors 824 include a biometric sensor, it may include biometric sensing circuitry, as well as portions of a crown that conductively couple a user's body to the biometric sensing circuitry. Biometric sensing circuitry may include components such as processors, capacitors, inductors, transistors, analog-to-digital converters, or the like.

The device 800 may also include a touch sensor 820 that is configured to determine a location of a touch on a touch-sensitive surface of the device 800 (e.g., an input surface defined by the display 108). The touch sensor 820 may use or include capacitive sensors, resistive sensors, surface acoustic wave sensors, piezoelectric sensors, strain gauges, or the like. In some cases, the touch sensor 820 associated with a touch-sensitive surface of the device 800 may include a capacitive array of electrodes or nodes that operate in accordance with a mutual-capacitance or self-capacitance scheme. The touch sensor 820 may be integrated with one or more layers of a display stack (e.g., the display 108) to provide the touch-sensing functionality of a touchscreen. Moreover, the touch sensor 820, or a portion thereof, may be used to sense motion of a user's finger as it slides along a surface of a crown, as described herein.

The device 800 may also include a force sensor 822 that is configured to receive and/or detect force inputs applied to a user input surface of the device 800 (e.g., the display 108). The force sensor 822 may use or include capacitive sensors, resistive sensors, surface acoustic wave sensors, piezoelectric sensors, strain gauges, or the like. In some cases, the force sensor 822 may include or be coupled to capacitive sensing elements that facilitate the detection of changes in relative positions of the components of the force sensor (e.g., deflections caused by a force input). The force sensor 822 may be integrated with one or more layers of a display stack (e.g., the display 108) to provide force-sensing functionality of a touchscreen.

The device 800 may also include a communication port 828 that is configured to transmit and/or receive signals or electrical communication from an external or separate device. The communication port 828 may be configured to couple to an external device via a cable, adaptor, or other type of electrical connector. In some examples, the communication port 828 may be used to couple the device 800 to an accessory, including a dock or case, a stylus or other input device, smart cover, smart stand, keyboard, or other device configured to send and/or receive electrical signals.

As used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

One may appreciate that although many embodiments are disclosed above, that the operations and steps presented with respect to methods and techniques described herein are meant as exemplary and accordingly are not exhaustive. One may further appreciate that alternate step order or fewer or additional operations may be required or desired for particular embodiments.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

What is claimed is:

1. A portable electronic device comprising:
a housing defining an external side surface; and
a button assembly positioned along the external side surface of the housing and comprising a button portion, the button portion comprising:
a metal base movably coupled to the housing;
a metal cap coupled to the metal base and defining a user input surface;
an intermediate structure comprising a dielectric material positioned between the metal cap and the metal base, the intermediate structure bonding the metal cap to the metal base; and
an electrical component positioned in the intermediate structure and between the metal cap and the metal base, the electrical component conductively coupled to the metal cap and the metal base.

2. The portable electronic device of claim 1, wherein:
the portable electronic device further comprises:
an electrode positioned along the external side surface of the housing and configured to contact a first portion of a user's finger; and
a biometric sensing system configured to measure a physiological parameter of a user based at least in part on a signal from the electrode; and
the intermediate structure of the button portion electrically isolates a second portion of the user's finger that is that is in contact with the user input surface from the housing.

3. The portable electronic device of claim 1, wherein the dielectric material at least partially encapsulates the electrical component.

4. The portable electronic device of claim 1, wherein the electrical component is a transient voltage suppression diode configured to conductively decouple the metal cap from the metal base under a first condition and conductively couple the metal cap to the metal base under a second condition.

5. The portable electronic device of claim 1, wherein the electrical component comprises a fuse.

6. The portable electronic device of claim 1, wherein:
the button assembly further comprises a printed circuit board at least partially embedded in the intermediate structure; and
the electrical component is coupled to the printed circuit board.

7. The portable electronic device of claim 1, wherein:
the user input surface protrudes from the external side surface; and
the metal base is recessed with respect to the external side surface.

8. An electronic watch comprising:
a display;
a housing at least partially surrounding the display, the housing defining an external side surface;
a first input member defining a first user input surface, the first input member positioned along the external side surface of the housing, the first input member configured to receive a signal from a portion of a user's skin in contact with the first user input surface; and
a second input member positioned along the external side surface of the housing and comprising:
a metal cap defining a second user input surface;
a metal base movably coupled to the housing; and
an intermediate structure between the metal cap and the metal base, the intermediate structure comprising a dielectric material configured to conductively isolate the metal cap from the metal base.

9. The electronic watch of claim 8, wherein:
the first input member is a crown configured to receive a rotational input;
the signal received is detected by an electrocardiogram sensor configured to measure a physiological parameter of the user; and
the second input member is a button configured to receive a translational input.

10. The electronic watch of claim 8, further comprising an electrical component electrically coupled to the metal cap and the metal base, the electrical component embedded in the intermediate structure.

11. The electronic watch of claim 10, wherein:
the dielectric material comprises a molded polymer material that bonds the metal cap to the metal base; and
the dielectric material separates the metal cap and the metal base.

12. The electronic watch of claim 10, wherein the electrical component is a transient-voltage-state (TVS) diode configured to isolate the metal cap from the metal base at a voltage range comprising an ECG signal voltage.

13. The electronic watch of claim 12, wherein the TVS diode is configured to conduct current from the metal cap to the metal base to ground the metal cap at an electrostatic discharge voltage.

14. The electronic watch of claim 10, wherein the electrical component is configured to conductively couple the metal cap to the metal base in response to a voltage condition between the metal cap and the metal base.

15. An electronic device comprising:
a metal housing; and
a button assembly comprising a button portion positioned partially within a recess defined by the metal housing, the button portion configured to be depressed by a user input applied thereto, the button portion comprising:
a cap defining a conductive surface and configured to receive the user input;
a base conductively coupled to the metal housing;
an electrical component coupled to the cap and to the base, the electrical component configured to:
in a first state, conduct current from the cap to the base; and
in a second state, effectively isolate the cap to the base; and
a polymer member formed between the cap and the base and mechanically coupled to the electrical component.

16. The electronic device of claim 15, wherein the button portion further comprises a gasket positioned over a portion of a peripheral surface of the button portion, the gasket concealing a peripheral surface of the polymer member.

17. The electronic device of claim 16, wherein the electrical component is encapsulated in the polymer member and electrically coupled to the cap or the base.

18. The electronic device of claim 15, wherein the polymer member is formed within a gap defined between the cap and the base.

19. The electronic device of claim 15, wherein the electrical component is soldered to the cap and the base.

20. The electronic device of claim 15, wherein the polymer member defines a gasket portion configured to define a seal between the button portion and the metal housing.
